(19) United States
(12) Patent Application Publication
(10) Pub. No.: US 2018/0216244 A1
(43) Pub. Date: Aug. 2, 2018

(54) PHOTOELECTRODE, METHOD FOR PRODUCING SAME AND PHOTOELECTROCHEMICAL CELL

(71) Applicants: Panasonic Intellectual Property Management Co., Ltd, Osaka-shi, Osaka (JP); Geomatec Co., Ltd., Yokohama-shi, Kanagawa (JP)

(72) Inventors: Takaiki NOMURA, Osaka (JP); Takahiro ITO, Kanagawa (JP); Kazuhito HATO, Osaka (JP)

(21) Appl. No.: 15/746,581

(22) PCT Filed: Jun. 14, 2016
(86) PCT No.: PCT/JP2016/002874

§ 371 Date: Jan. 22, 2018

(30) Foreign Application Priority Data
Jul. 24, 2015 (JP) 2015-146998

(51) Int. Cl. C25B 11/04; C25B 1/00; C25B 1/04; C25B 9/06; C30B 23/02; C30B 25/04; C30B 25/18; C30B 29/16; C30B 29/38; C30B 29/68

(52) U.S. Cl. CPC C25B 11/0478; C25B 1/003; C25B 1/04; C25B 11/0405; C25B 9/06; C30B 29/68; C30B 25/04; C30B 25/18; C30B 29/16; C30B 29/38; C30B 23/025

(57) ABSTRACT

A photoelectrode (120) of the present disclosure includes: a substrate (121); a ZnO conductive film (122) which is provided on the substrate (121) and in which Zn is partially substituted by at least one element selected from Ga and Al; and a semiconductor film (123) which is provided on an opposite side of the substrate (121) with respect to the ZnO conductive film (122) and which is composed of a nitride or an oxynitride of at least one metal element selected from metal elements of groups 4A, 5A, 6A, and 3B.

### TECHNICAL FIELD

The present disclosure relates to a photoelectrode, a method for producing the photoelectrode, and a photoelectrochemical cell.

### BACKGROUND ART

There are conventionally known techniques for splitting water to obtain hydrogen and oxygen by irradiating a semiconductor material serving as a photoelectrode with light (see, for example, Patent Literature 1). Patent Literature 1 discloses a technique in which an n-type semiconductor electrode (photoelectrode) and a counter electrode are disposed in an electrolyte solution and the surface of the n-type semiconductor electrode is irradiated with light to obtain hydrogen and oxygen evolved from the surfaces of these electrodes. Specifically, Patent Literature 1 describes the use of a TiO₂ electrode or the like as the n-type semiconductor electrode. However, since the band gap of (anatase-type) TiO₂ is 380 nm, only about 1% of sunlight can be utilized in a TiO₂ electrode. In order to solve this problem, Patent Literature 2 discloses a combination of an ITO film as a conductive substrate and a Nb₃N₅ film having a small band gap (from 700 nm to 1010 nm) as a photoelectrode formed on the ITO film by MOCVD, in which an organic Nb compound and ammonia are brought into contact with each other on the ITO film, to increase the sunlight utilization efficiency.

### CITATION LIST

### Patent Literature

Patent Literature 1 JP 51(1976)-123779 A

Patent Literature 2 WO 2013/084447 A1

### SUMMARY OF INVENTION

### Technical Problem

However, the synthesis process of Patent Literature 2 using ammonia has the following difficulties. Conductive materials such as ITO used for conventional conductive substrates lack stability in an ammonia atmosphere. However, in order to form a photoelectrode including a semiconductor film composed of a metal nitride or a metal oxynitride, the metal nitride or metal oxynitride must be synthesized in contact with ammonia at a high temperature of, for example, 500° C. or higher. Therefore, it is difficult to produce such a photoelectrode without reducing the conductivity of a conductive material such as ITO.

It is therefore an object of the present disclosure to provide a photoelectrode including a semiconductor film composed of a metal nitride or a metal oxynitride which requires relatively high temperature synthesis using ammonia but capable of achieving high quantum efficiency (optical semiconductor properties for water splitting under light irradiation to obtain hydrogen and oxygen) without reducing the conductivity of a conductive material used in the photoelectrode.

### Solution to Problem

The present disclosure provides a photoelectrode including: a substrate; a ZnO conductive film which is provided on the substrate and in which Zn is partially substituted by at least one element selected from Ga and Al; and a semiconductor film which is provided on an opposite side of the substrate with respect to the ZnO conductive film and which is composed of a nitride or an oxynitride of at least one metal element selected from metal elements of groups 4A, 5A, 6A, and 3B.

### Advantageous Effects of Invention

According to the present disclosure, it is possible to provide a photoelectrode including a semiconductor film composed of a metal nitride or a metal oxynitride which requires relatively high temperature synthesis using ammonia but capable of achieving high quantum efficiency (i.e., in the present disclosure, optical semiconductor properties for water splitting under light irradiation to obtain hydrogen and oxygen) without reducing the conductivity of a conductive material used in the photoelectrode.

### BRIEF DESCRIPTION OF DRAWINGS

FIG. 1 is a schematic diagram illustrating a configuration of a photoelectrochemical cell including one example of a photoelectrode according to one embodiment of the present disclosure.

FIG. 2 is a schematic diagram illustrating a configuration of a photoelectrochemical cell including another example of the photoelectrode according to one embodiment of the present disclosure.

FIG. 3 is a graph showing sheet resistances of ZnO conductive films (GZO films) used in Example 1, each in which Zn is partially substituted by Ga.

FIG. 4 shows thin-film XRD (X-ray Diffraction) spectra of the GZO films used in Example 1.

FIG. 5 shows a UV-Vis (Ultraviolet Visible Absorption Spectroscopy) spectrum of a photoelectrode of Example 1.

FIG. 6 shows an XPS (X-ray Photoelectron Spectroscopy) spectrum at a depth of 10 nm from the surface of a NbON film in the photoelectrode of Example 1.

FIG. 7 shows an AES (Auger Electron Spectroscopy) spectrum from the surface of the NbON film in the photoelectrode of Example 1.

FIG. 8 is a graph showing quantum efficiencies of photoelectrodes of Examples 1 and 2.

FIG. 9 shows an AES spectrum from the surface of a NbON film in a photoelectrode of Comparative Example 1.

FIG. 10 shows a UV-Vis spectrum of a photoelectrode of Example 3.

FIG. 11 shows an XPS spectrum at a depth of 10 nm from the surface of a Nb₃N₅ film in the photoelectrode of Example 3.

FIG. 12 is a graph showing sheet resistances of GZO films used in Example 3.

FIG. 13 is a graph showing quantum efficiencies of photoelectrodes of Examples 3 and 4.

FIG. 14 shows an XPS spectrum at a depth of 10 nm from the surface of a TaON film in a photoelectrode of Example 5.

FIG. 15 is a graph showing sheet resistances of GZO films used in Example 5.

FIG. 16 is a graph showing quantum efficiencies of photoelectrodes of Example 5.

FIG. 17 shows an XPS spectrum at a depth of 10 nm from the surface of a Ta₃N₅ film in a photoelectrode of Example 6.

FIG. 18 is a graph showing sheet resistances of GZO films used in Example 6.

FIG. 19 is a graph showing quantum efficiencies of photoelectrodes of Example 6.

### DESCRIPTION OF EMBODIMENTS

A photoelectrode according to a first aspect of the present disclosure includes: a substrate; a ZnO conductive film which is provided on the substrate and in which Zn is partially substituted by at least one element selected from Ga and Al; and a semiconductor film which is provided on an opposite side of the substrate with respect to the ZnO conductive film and which is composed of a nitride or an oxynitride of at least one metal element selected from metal elements of groups 4A, 5A, 6A, and 3B.

The photoelectrode according to the first aspect includes a ZnO conductive film in which Zn is partially substituted by at least one element selected from Ga and Al. Therefore, it is possible to produce a semiconductor film composed of a nitride or an oxynitride of at least one metal element selected from metal elements of groups 4A, 5A, 6A, and 3B, which requires relatively high temperature synthesis using ammonia, without reducing the conductivity of the ZnO conductive film. As a result, the photoelectrode according to the first aspect can achieve high quantum efficiency.

In a second aspect, for example, in the photoelectrode according to the first aspect, a ratio of a total number of Ga atoms and Al atoms to a total number of Zn atoms, Ga atoms, and Al atoms in the ZnO conductive film may be 2 at % or more and 6 at % or less in atomic percent.

In the photoelectrode according to the second aspect, the ZnO conductive film has high conductivity. Therefore, the quantum efficiency can be further increased.

In a third aspect, for example, in the photoelectrode according to the second aspect, the ratio of the total number of Ga atoms and Al atoms to the total number of Zn atoms, Ga atoms, and Al atoms in the ZnO conductive film may be 2 at % or more and 4 at % or less in atomic percent.

In the photoelectrode according to the third aspect, the ZnO conductive film can be an epitaxial film. When the ZnO conductive film is an epitaxial film, the crystal orientation of the ZnO conductive film is very good, and a defect very rarely occurs within the film or at the interfaces with other films. Therefore, the quantum efficiency can be still further increased.

In a fourth aspect, for example, in the photoelectrode according to any one of the first to third aspects, the ZnO conductive film may be an epitaxial film.

In the photoelectrode according to the fourth aspect, the ZnO conductive film is an epitaxial film. The crystal orientation of the ZnO conductive film is very good, and a defect very rarely occurs within the film or at the interfaces with other films. Therefore, the quantum efficiency can be still further increased.

In a fifth aspect, for example, the photoelectrode according to any one of the first to fourth aspects may further include a ZnO semiconductor film disposed between the ZnO conductive film and the semiconductor film.

In the photoelectrode according to the fifth aspect, the ZnO semiconductor film serves as a charge separation layer. In addition, this semiconductor film contains the same crystalline material ZnO as the ZnO conductive film, and thus a defect very rarely occurs at the interface with the ZnO conductive film. Therefore, the quantum efficiency can be still further increased.

In a sixth aspect, for example, in the photoelectrode according to the fifth aspect, the ZnO semiconductor film may be an epitaxial film.

In the photoelectrode according to the sixth aspect, the ZnO semiconductor film is an epitaxial film. Therefore, the crystal orientation of the ZnO semiconductor film is very good, and a defect very rarely occurs within the film or at the interfaces with other films. As a result, the quantum efficiency can be still further increased.

In a seventh aspect, for example, in the photoelectrode according to any one of the first to sixth aspects, a portion of the ZnO conductive film may be exposed without being covered with the semiconductor film.

In the photoelectrode according to the seventh aspect, the conductivity of the ZnO conductive film does not decrease even when it is brought into contact with ammonia under high-temperature conditions to form a semiconductor film composed of a metal nitride or a metal oxynitride thereon. Therefore, the exposed portion of the ZnO conductive film can be used directly as an electrode extraction portion. In addition, the exposed portion of this ZnO conductive film can be easily produced because it can be formed using a simple metal mask instead of a protective film or the like.

In an eighth aspect, for example, in the photoelectrode according to any one of the first to seventh aspects, the semiconductor film may be a semiconductor film composed of at least one selected from a Nb nitride, a Ta nitride, a Nb oxynitride, and a Ta oxynitride.

The photoelectrode according to the eighth aspect makes it possible not only to utilize the visible light region of sunlight to split water to obtain hydrogen and oxygen but also to increase the quantum efficiency.

In a ninth aspect, for example, in the photoelectrode according to the eighth aspect, the semiconductor film may be a semiconductor film composed of at least one nitride selected from Nb₃N₅ and Ta₃N₅.

The photoelectrode according to the ninth aspect makes it possible not only to utilize the visible light region of sunlight to split water to obtain hydrogen and oxygen but also to further increase the quantum efficiency.

In a tenth aspect, for example, in the photoelectrode according to the eighth aspect, the semiconductor film may be a semiconductor film composed of at least one oxynitride selected from NbON and TaON.

The photoelectrode according to the tenth aspect makes it possible not only to utilize the visible light region of sunlight to split water to obtain hydrogen and oxygen but also to further increase the quantum efficiency.

A photoelectrochemical cell according to an eleventh aspect of the present disclosure includes: the photoelectrode according to any one of the first to tenth aspects; a counter electrode electrically connected to the ZnO conductive film of the photoelectrode; and a container containing the photoelectrode and the counter electrode.

The photoelectrochemical cell according to the eleventh aspect includes the photoelectrode according to any one of the first to tenth aspects. Therefore, it is possible to split water to obtain hydrogen and oxygen with high quantum efficiency.

In a twelfth aspect, the photoelectrochemical cell according to the eleventh aspect may further include a water-containing electrolyte solution in contact with a surface of the photoelectrode and a surface of the counter electrode in the container.

The photoelectrochemical cell according to the twelfth aspect makes it possible to split water to obtain hydrogen and oxygen with high quantum efficiency.

A thirteenth aspect of the present disclosure provides a method for producing a photoelectrode, including: forming, on a substrate, a ZnO conductive film in which Zn is partially substituted by at least one element selected from Ga and Al; and forming, on an opposite side of the substrate with respect to the ZnO conductive film, a semiconductor film composed of a nitride or an oxynitride of at least one metal element selected from metal elements of groups 4A, 5A, 6A, and 3B, using ammonia.

In the photoelectrode production method according to the thirteenth aspect, the conductivity of the ZnO conductive film does not decrease when the semiconductor film is formed using ammonia. Therefore, the photoelectrode thus produced can achieve high quantum efficiency.

Hereinafter, embodiments of a photoelectrode and a photoelectrochemical cell of the present disclosure are described in detail with reference to drawings.

The following embodiments are merely examples, and the present disclosure is not limited to the following embodiments.

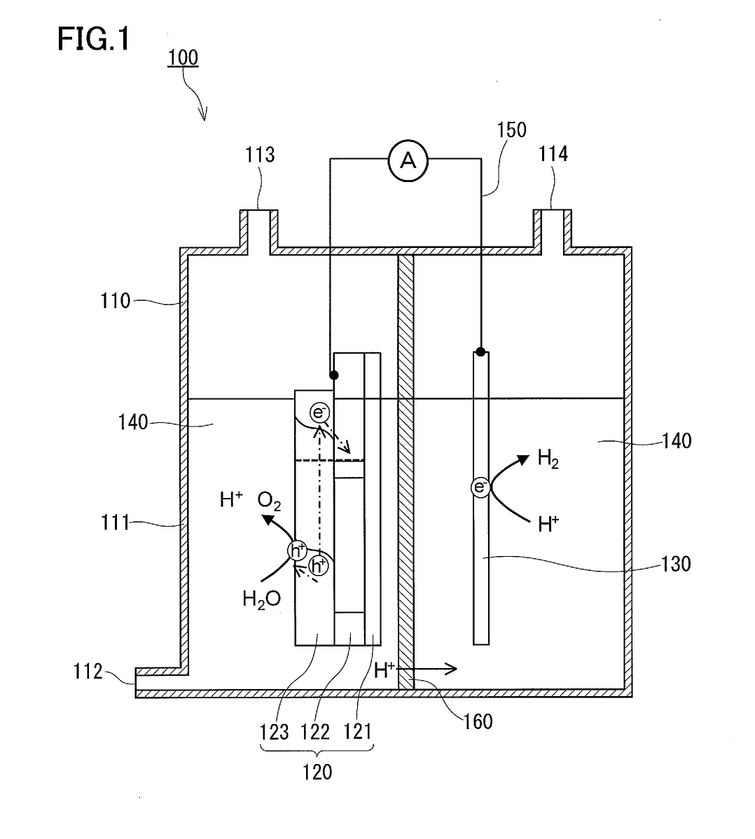

FIG. 1 shows one example of a configuration of a photoelectrochemical cell including one example of a photoelectrode according to one embodiment of the present disclosure. A photoelectrochemical cell 100 shown in FIG. 1 includes: a photoelectrode 120; a counter electrode 130; a water-containing electrolyte solution 140; and a container 110 containing the photoelectrode 120, the counter electrode 130, and the electrolyte solution 140.

The photoelectrode 120 includes: a substrate 121; a ZnO conductive film 122 which is provided on the substrate 121 and in which Zn is partially substituted by at least one element selected from Ga and Al; and a semiconductor film 123 which is provided on the ZnO conductive film 122 and is composed of a nitride or an oxynitride of at least one metal element selected from metal elements of groups 4A, 5A, 6A, and 3B. As an example, the case where the semiconductor film 123 is a semiconductor film composed of a Nb oxynitride, more specifically, a NbON film, is described herein.

In the container 110, the photoelectrode 120 and the counter electrode 130 are disposed so that their surfaces are in contact with the electrolyte solution 140. A portion of the container 110 (hereinafter referred to as a light incident portion 111) that faces the semiconductor film 123 of the photoelectrode 120 placed in the container 110 is made of a material that transmits light such as sunlight.

The ZnO conductive film 122 in the photoelectrode 120 and the counter electrode 130 are electrically connected by a conducting wire 150. As used herein, the counter electrode refers to an electrode that can exchange electrons with the photoelectrode without the presence of the electrolyte solution. Accordingly, in the present embodiment, there is no particular limitation on the positional relationship, etc. between the counter electrode 130 and the photoelectrode 120 as long as the counter electrode 130 is connected electrically to the ZnO conductive film 122 of the photoelectrode 120. It should be noted that since the NbON used in the semiconductor film 123 in the present embodiment is an n-type semiconductor, the counter electrode 130 serves as an electrode that receives electrons directly from the photoelectrode 120 without the presence of the electrolyte solution 140. It is preferable to use a material with a low overvoltage for the counter electrode 130. For example, it is preferable to use a metal catalyst such as Pt, Au, Ag, Fe, or Ni as the counter electrode 130 because the use of such a metal catalyst increases the activity of the counter electrode 130.

As shown in FIG. 1, the photoelectrochemical cell 110 further includes a separator 160. The separator 160 separates the interior of the container 110 into two regions: a region in which the photoelectrode 120 is disposed; and a region in which the counter electrode 130 is disposed. The electrolyte solution 140 is placed in both of these regions. The container 110 includes an oxygen outlet 113 for discharging oxygen generated in the region in which the photoelectrode 120 is disposed, and a hydrogen outlet 114 for discharging hydrogen generated in the region in which the counter electrode 130 is disposed. The container 110 further includes a water inlet 112 for supplying water into the container 110.

The electrolyte solution 140 is not particularly limited as long as it contains water. It should be noted that the electrolyte solution 140 may be acidic or alkaline. It is also possible to use a solid electrolyte instead of the electrolyte solution 140.

A more specific configuration of the photoelectrode 120 is described below, together with one example of the production method of the photoelectrode 120.

For example, a sapphire substrate can be used as the substrate 121. The ZnO conductive film 122, in which Zn is partially substituted by at least one element selected from Ga and Al, can be formed on a heated sapphire substrate by performing sputtering, in an inert gas flow atmosphere, using a ZnO target, in which Zn is partially substituted by at least one element selected from Ga and Al. Then, a metal mask, for example, is placed on a portion serving as an electrode extraction portion of the ZnO conductive film 122 formed on the substrate 121. Then, in a MOCVD apparatus, a gas mixture obtained by mixing a starting material (e.g., an organic Nb compound) vaporized in an inert gas flow atmosphere, with ammonia and water vapor is injected onto the ZnO conductive film 122. Thus, a NbON film can be formed thereon (by MOCVD). It should be noted that in the MOCVD, oxygen may be used instead of water vapor.

Not only sapphire but also other substrate materials such as metal, glass, and ceramics can be used for the substrate 121. In order to form the ZnO conductive film 122 by epitaxial deposition, it is preferable to use, as the substrate 121, an oriented substrate such as C-plane sapphire or R-plane sapphire. It is more preferable to subject such an oriented substrate to STEP treatment.

In the ZnO conductive film 122, the ratio of the total number of Ga atoms and Al atoms to the total number of Zn atoms, Ga atoms, and Al atoms may be, for example, 2 at % or more and 6 at % or less in atomic percent. When the ratio of the total number of Ga atoms and Al atoms is within this range, the sheet resistance of the ZnO conductive film 122 can be reduced to, for example, 30 Ω/sq or less. Thereby, the resistance loss, etc. of the ZnO conductive film 121 is reduced, and thus the quantum efficiency of the photoelectrode 120 can be increased. Furthermore, when the ratio of the total number of Ga atoms and Al atoms is, for example, 2 at % or more and 4 at % or less, if the substrate 121 is an oriented substrate, such as a sapphire substrate with C-plane or R-plane exposed on its surface, the ZnO conductive film 122 can be an epitaxial film. Therefore, in this case, the quantum efficiency of the photoelectrode 122 can be further increased. In the case where some Zn atoms in the ZnO conductive film 122 are substituted by only Ga atoms, the ratio mentioned above refers to the ratio of the number of Ga atoms to the total number of Zn atoms and Ga atoms. In the case where some Zn atoms in the ZnO conductive film 122 are substituted by only Al atoms, the ratio mentioned above refers to the ratio of the number of Al atoms to the total number of Zn atoms and Al atoms.

During sputtering to form the ZnO conductive film 122, the temperature of the substrate 121 may be, for example, from room temperature up to 300° C. The temperature of the substrate 121 of 350° C. or higher, for example, may cause a difference between the composition of the sputtering target and that of the resulting film. The inert gas used to form the ZnO conductive film 122 by sputtering may be not only a so-called rare gas such as He, Ne, Ar, Kr, or Xe but also nitrogen gas or the like. It is desirable, however, to use a gas having a low content of oxygen and water as the inert gas.

As an organic niobium compound used to form the semiconductor film 123, for example, R¹N=Nb(NR²R³)₃, where R¹, R², and R³ are each independently a hydrocarbon group, can be used. The use of such an organic niobium compound as a starting material can prevent the self-condensation reaction of the starting material. R¹ is suitably a branched-chain hydrocarbon group because the resulting material is a liquid and thus is easy to handle, is easily vaporized, easily undergoes a homogeneous reaction, and further has a higher decomposition temperature. In particular, a tertiary butyl group (—C(CH₃)₃) is desirably used, as R¹. As R² and R³, straight-chain hydrocarbon groups are suitable because the resulting material has a higher decomposition temperature. For example, CH₃— and C₂H₅— are desirable, as R² and R³. A longer carbon chain may cause too high decomposition temperature. The temperature at which the semiconductor film 123 is formed by MOCVD (i.e., the temperature of the substrate 121) should be the decomposition temperature of the starting material or higher. The decomposition temperature of the starting material can be determined by TG-DTA measurement using an inert gas flow, DSC measurement in a sealed container, or the like. For example, in the case where R¹ is a tertiary butyl group (—C(CH₃)₃) and R² and R³ are CH₃— and C2H₅—, respectively, in R¹N=Nb(NR²R³)₃, the deposition temperature is, for example, 250° C. or higher, and may be 500° C. or higher to form a uniform film.

Next, the operation of the photoelectrode 120 and that of the photoelectrochemical cell 100 are described with reference to FIG. 1.

When the semiconductor film 123 disposed in contact with the electrolyte solution 140 in the container 110 of the photoelectrochemical cell 100 is irradiated with sunlight incident through the light incident portion 111 of the container 110, electrons are generated in the conduction band of the semiconductor film 123 and holes are generated in the valence band thereof. The holes thus generated move to the surface of the semiconductor film 123 due to band bending by a depletion layer formed as a result of contact with the electrolyte solution 140. On the surface of the semiconductor film 123, water is split according to the reaction formula (1) below and thus oxygen is produced. On the other hand, the electrons move to the ZnO conductive film 122 due to the above-mentioned band bending and then reach the counter electrode 130. At the counter electrode 130, hydrogen is produced according to the reaction formula (2) below.

4h⁺+H₂O→O₂↑4 H⁺ (1)

4e⁻+4 H⁺→2H₂↑ (2)

The hydrogen and oxygen thus produced are separated from each other by the separator 160, and oxygen is discharged from the oxygen outlet 113 while hydrogen is discharged from the hydrogen outlet 114. Water to be split is supplied into the container 110 through the inlet 112.

Since the NbON used in the semiconductor film 123 has excellent optical semiconductor properties, the probability of recombination of holes and electrons is low. Therefore, the photoelectrode 120 has high quantum efficiency of hydrogen evolution reaction by light irradiation. In addition, since this NbON has a small band gap, it is also responsive to visible light in sunlight. As a result, the photoelectrode 120 can produce more hydrogen.

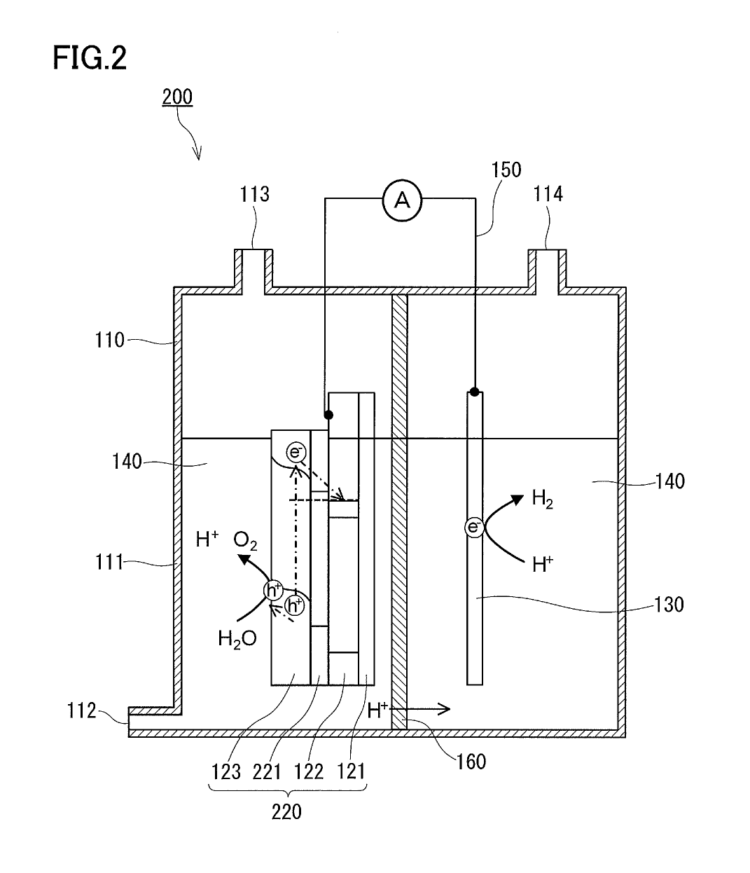

Another example of the configuration of the photoelectrode of the present embodiment is a photoelectrode 220 used in a photoelectrochemical cell 200 shown in FIG. 2. The photoelectrode 220 is different from the photoelectrode 120 in that the former further includes a ZnO semiconductor film 221 disposed between the ZnO conductive film 122 and the semiconductor film 123. Unlike the ZnO conductive film 122, the ZnO semiconductor film 221 does not serve as a conductive film in which Zn is partially substituted by at least one element selected from Ga and Al, but serves as a semiconductor. Therefore, the ZnO semiconductor film 221 does not contain at least one element of Ga and Al, for example.

The ZnO semiconductor film 221 serves as a charge separation layer. Therefore, the photoelectrode 220 can efficiently separate holes and electrons generated by irradiation of light, and thus can further increase the quantum efficiency compared to the photoelectrode 120. In addition, the ZnO semiconductor film 221 contains the same crystalline material ZnO as the ZnO conductive fi1m122, and a defect very rarely occurs at the interface with the ZnO conductive film 122. Therefore, the quantum efficiency can be still further increased.

The ZnO semiconductor film 221 may be an epitaxial film. When the ZnO semiconductor film 221 is an epitaxial film, the crystal orientation of the ZnO semiconductor film 221 is very good, and a defect very rarely occurs within the film or at the interfaces with other films such as the ZnO conductive film 122 and the semiconductor film 123. Therefore, the quantum efficiency can be still further increased.

One example of the production method of the photoelectrode 220 is described. For example, the ZnO conductive film 122 is first formed on the substrate 121 in the same manner as in the production method of the photoelectrode 120. Next, in an inert gas flow atmosphere, sputtering is performed using, for example, a previously prepared ZnO target containing neither Ga nor Al, so that the ZnO semiconductor film 221 can be formed on the ZnO conductive film 122. Then, for example, a NbON film can be formed on the ZnO semiconductor film 221 in the same manner as in the formation of the semiconductor film 123 of the photoelectrode 120.

In the configuration examples of the photoelectrode shown in FIGS. 1 and 2, a NbOn film is described as an example of the semiconductor film 123. However, the semiconductor film 123 is not limited to a NbON film. It is possible to use, as the semiconductor film 123, any semiconductor film composed of a nitride or an oxynitride of at least one metal element selected from metal elements of groups 4A, 5A, 6A, and 3B. The use of such a semiconductor film achieves high quantum efficiency as in the case of a NbON film. It can be said that the configuration of the photoelectrode of the present disclosure is highly effective particularly when a Nb nitride (such as Nb₃N₅), a Ta nitride (such as Ta₃N₅), a Nb oxynitride (such as NbON), or a Ta oxynitride (such as TaON) is used among the nitrides and oxynitrides of at least one metal element selected from metal elements of groups 4A, 5A, 6A, and 3B. These nitrides and oxynitrides require relatively high temperature (for example, 500° C. or higher) synthesis using ammonia. Therefore, combined use with the ZnO conductive film specified in the photoelectrode of the present disclosure makes it possible to synthesize these nitrides and oxynitrides without reducing the conductivity of the ZnO conductive film. In addition, the use of these nitrides and oxynitrides makes it possible not only to utilize the visible light region of sunlight to split water to obtain hydrogen and oxygen but also to increase the quantum efficiency of the photoelectrode.

In order to form a semiconductor film of a Nb nitride (such as Nb₃N₅) by MOCVD, for example, MOCVD can be performed in the same manner as in the MOCVD of the NbON film described above as an example, except that a gas mixture containing no water vapor is used instead of the gas mixture containing both ammonia and water vapor. In order to form a semiconductor film of a Ta oxynitride (such as TaON) or a Ta nitride (such as Ta₃N₅) by MOCVD, for example, MOCVD can be performed in the same manner as in the MOCVD of the NbON film or the Nb₃N₅ film described above as an example using the same gas mixture, except that an appropriately selected Ta compound is used as a starting material. It is also possible to form a semiconductor film of a nitride or an oxynitride containing a metal element other than Nb and Ta by MOCVD using an appropriately selected starting material in the same manner as in the formation of a semiconductor film of a Nb nitride or a Nb oxynitride.

An exposed portion of the conductive member of the photoelectrode 120 or 220 that is not coated with another film (for example, in the case where the substrate 121 is a metal substrate, a surface of the substrate 121 on which the ZnO conductive film 122 is not disposed) may be coated with an insulating material such as resin. This coating can prevent the conductive material of the photoelectrode from dissolving into the electrolyte solution.

It should be noted that the components of the photoelectrochemical cells 100 and 200 other than the photoelectrodes 120 and 220, such as the container 110, the counter electrode 130, the conducting wire 150, the separator 160, etc., are not particularly limited, and any known container, conducting wire, separation membrane, etc. used in a photoelectrochemical cell capable of splitting water to produce gases such as hydrogen can be used as appropriate.

### EXAMPLES

Hereinafter, the present disclosure will be described in more detail in the following examples.

### Example 1

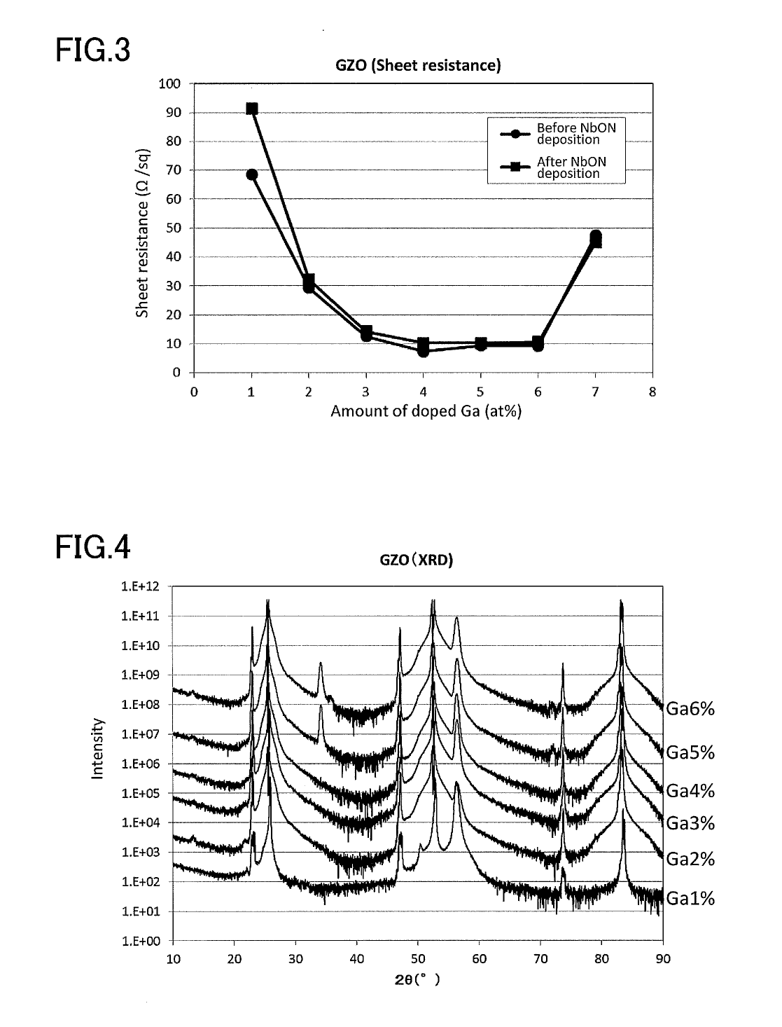

ZnO targets, respectively, in which 1 at %, 2 at %, 3 at %, 4 at %, 5 at %, 6 at %, 7 at %, and 8 at % of Zn were substituted by Ga, were prepared. Hereinafter “at %” is abbreviated as “%”, unless otherwise indicated. In a sputtering apparatus, sputtering was performed using each of the ZnO targets thus prepared in an Ar gas flow atmosphere at a flow rate of 3.38×10⁻³ Pa·m³/s (20 sccm), onto a (2-inch square) sapphire substrate heated to 300° C. and having R-plane exposed on its surface. Thus, GZO films, respectively, in which 1%, 2%, 3%, 4%, 5%, 6%, 7%, and 8% of Zn were substituted by Ga, were formed. FIG. 3 shows the sheet resistances of the GZO films thus obtained. As seen from the sheet resistances before NbON deposition shown in FIG. 3, the sheet resistances of the GZO films in which 2 to 6% of Zn was substituted by Ga were 30 Ω/sq or less. FIG. 4 shows the thin film XRD spectra of the GZO films. As seen from FIG. 4, the GZO films in which 4% or less of Zn was substituted by Ga were epitaxial films with only A-plane orientation.

A metal mask was placed on a portion (10 mm×2 inches) serving as an electrode extraction portion of each of the GZO films (GZO films in which 1%, 2%, 3%, 4%, 5%, 6%, 7%, and 8% of Zn were substituted by Ga) formed on the sapphire substrate. Then, in a MOCVD apparatus, a gas mixture obtained by mixing tertiary-butylimino tris-(ethylmethylamino)niobium ((CH₃)₃CN=Nb(N(C₂H₅)CH₃)₃) vaporized in a nitrogen gas flow (2.54×10⁻¹ Pa·m³/s (1500 sccm)) atmosphere, with ammonia (1.69×10⁻³ Pa·m³/s (10 sccm)) and water vapor (1.69×10⁻⁵ Pa·m³/s (0.1 sccm)) was injected onto each of the GZO films so as to form a NbON film thereon (by MOCVD). Thus, a photoelectrode of Example 1 including a sapphire substrate, a GZO film provided on the sapphire substrate, and a NbON film provided on the GZO film was obtained.

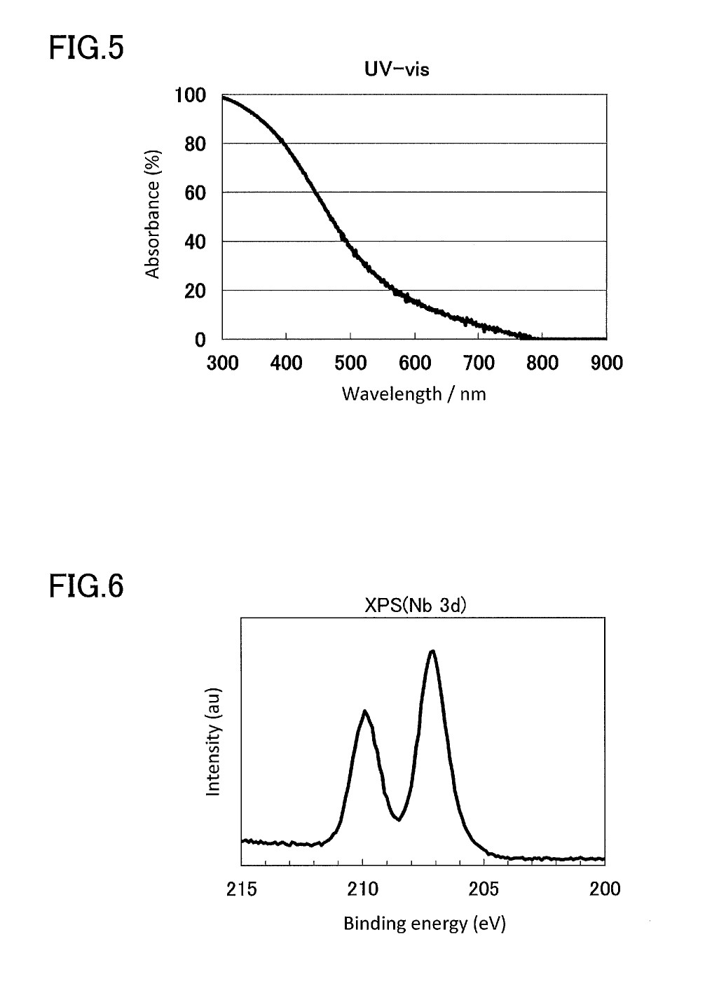

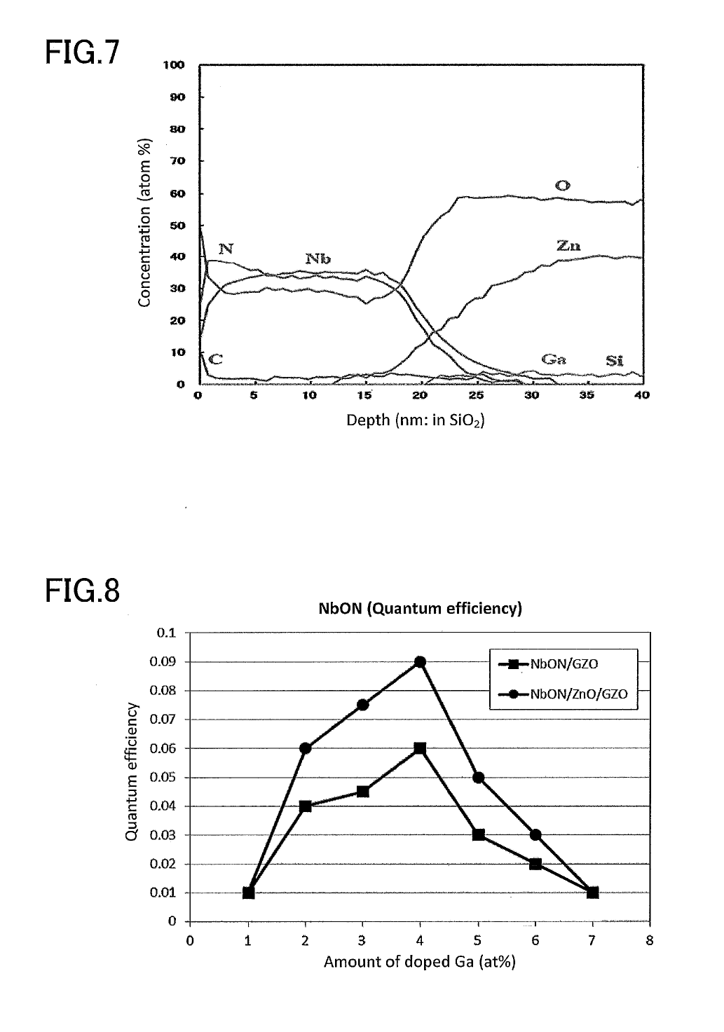

FIG. 5 shows the UV-Vis spectrum of the photoelectrode of Example 1 thus obtained. FIG. 6 shows the XPS spectrum at a depth of 10 nm from the surface of the NbON film in the photoelectrode of Example 1. FIG. 7 shows the AES spectrum from the surface of the NbON film in the photoelectrode of Example 1.

These results confirmed that the film composition of the NbON film was almost equal to Nb/O/N=1/1/1 and thus NbON was produced. Furthermore, the AES spectrum of FIG. 7 revealed that the GZO film remained unchanged and thus the photoelectrode of Example 1 had a two-layer structure of a GZO film and a NbON film. FIG. 3 shows the sheet resistance of an exposed portion (electrode extraction portion) of each GZO film in the photoelectrode of Example 1 (the result “after NbON deposition” in FIG. 3). There was little difference in the sheet resistance before and after the formation of the NbON film, which indicates that the GZO film was remained unchanged even after the formation of the NbON film.

Next, a photoelectrochemical cell 100 shown in FIG. 1 was fabricated using the photoelectrode of Example 1. In this photoelectrochemical cell 100, 1 mol/L of NaOH aqueous solution was used as an electrolyte, and a Pt electrode was used as the counter electrode 130. This photoelectrochemical cell 100 was irradiated with sunlight from the photoelectrode 120 side, and the quantum efficiency was measured based on a photocurrent generated therein. FIG. 8 shows the result (the result of “NbON/GZO” in FIG. 8). This result confirmed that a photoelectrochemical cell using the photoelectrode of Example 1 could achieve high quantum efficiency, particularly a cell using the photoelectrode including a GZO film doped with 2 to 6% of Ga and having a low sheet resistance could achieve higher quantum efficiency, and more particularly a cell using the photoelectrode including an epitaxial GZO film doped with 2 to 4% of Ga could achieve even higher quantum efficiency

### Comparative Example 1

A photoelectrode of Comparative Example 1 was fabricated in the same manner as in Example 1, except that an ATO film (antimony-doped tin oxide film) was formed instead of a GZO film as a conductive film. The ATO film was formed under the same deposition conditions as in the formation of the GZO film of Example 1.

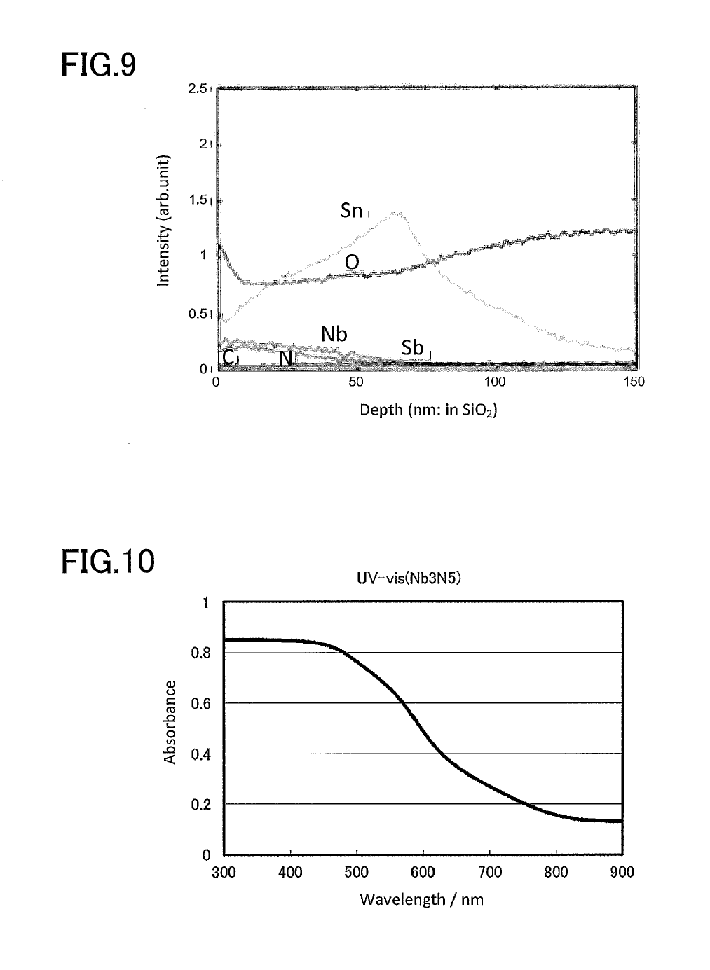

FIG. 9 shows the AES spectrum from the surface of the NbON film in the photoelectrode of Comparative Example 1. This AES spectrum indicates that tin (Sn) and antimony (Sb) as the components of the ATO film diffused into the NbON film and destroyed it. In fact, a photoelectrochemical cell was fabricated using the photoelectrode of Comparative Example 1 in the same manner as in Example 1, and an attempt was made to generate a photocurrent by irradiating the cell with sunlight from the photoelectrode side and measure the quantum efficiency based on the generated photocurrent. However, no photocurrent was observed.

### Example 2

A photoelectrode of Example 2 was fabricated in the same manner as in Example 1, except that a ZnO film was provided between the GZO film and the NbON film of the photoelectrode of Example 1. First, in a sputtering apparatus, sputtering was performed using each of the prepared ZnO targets in an Ar gas flow atmosphere at a flow rate of 3.38×10⁻³ Pa·m³/s (20 sccm), onto a (2-inch square) sapphire substrate heated to 300° C. and having R-plane exposed on its surface, in the same manner as in Example 1. Thus, GZO films, respectively, in which 1%, 2%, 3%, 4%, 5%, 6%, 7%, and 8% of Zn were substituted by Ga, were formed. Next, sputtering was performed using a ZnO target in which Zn was not substituted by Ga, so that a ZnO semiconductor film with a thickness of 50 nm was provided on each of the GZO films. Next, a NbON film was formed on the ZnO semiconductor film in the same manner as in Example 1. Thus, the photoelectrode of Example 2 was obtained.

A photoelectrochemical cell was fabricated using the photoelectrode of Example 2 in the same manner as in Example 1. This photoelectrochemical cell was irradiated with sunlight from the photoelectrode side, and the quantum efficiency was measured based on a photocurrent generated therein. FIG. 8 shows the result (the result of “NbON/ZnO/GZO” in FIG. 8). This result confirmed that a photoelectrochemical cell using the photoelectrode of Example 2 could achieve high quantum efficiency, particularly a cell using the photoelectrode including a GZO film doped with 2 to 6% of Ga and having a low sheet resistance could achieve higher quantum efficiency, and more particularly a cell using the photoelectrode including an epitaxial GZO film doped with 2 to 4% of Ga could achieve even higher quantum efficiency. Furthermore, it was also confirmed that, due to the charge separation effect of the ZnO film, the photoelectrode of Example 2 had higher quantum efficiency than the photoelectrode of Example 1 without a ZnO film provided therein.

### Example 3

A Nb₃N₅ film was formed instead of a NbON film by performing MOCVD in the same manner as in Example 1, except that only ammonia (1.69×10⁻³ Pa·m³/s (10 sccm) was injected onto a substrate instead of injecting a gas mixture containing ammonia (1.69×10⁻³ Pa·m³/s (10 sccm) and water vapor (1.69×10⁻⁵ Pa·m³/s (0.1 sccm)). Thus, the photoelectrode of Example 3 including a sapphire substrate, a GZO film provided on the sapphire substrate, and a Nb₃N₅ film provided on the GZO film was obtained.

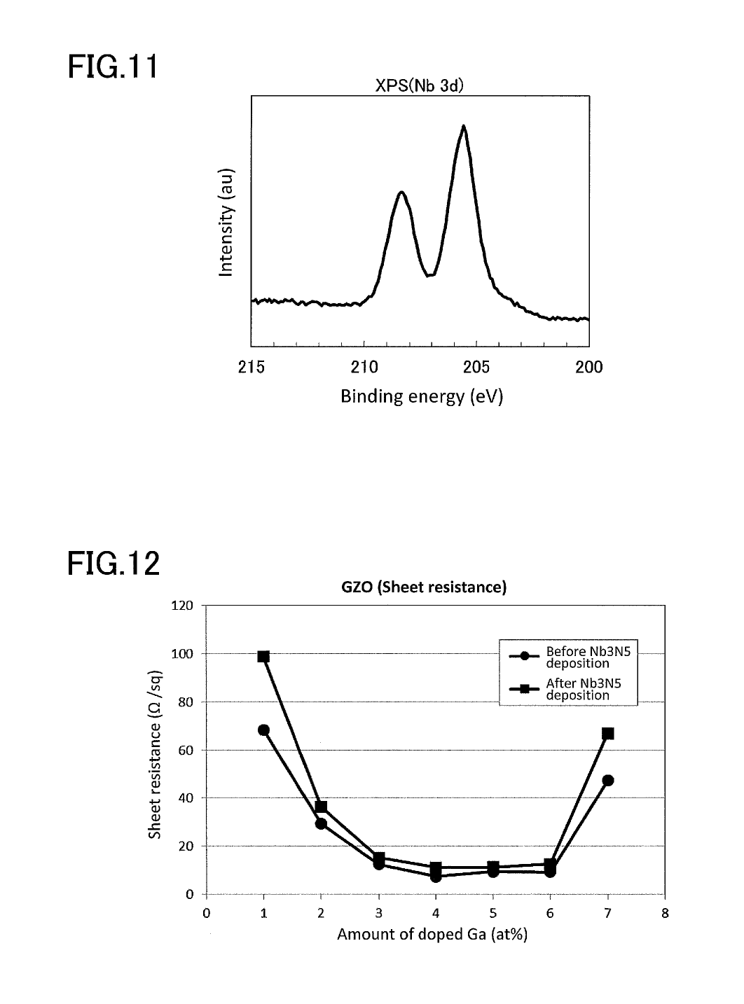

FIG. 10 shows the UV-Vis spectrum of the photoelectrode of Example 3 thus obtained. FIG. 11 shows the XPS spectrum at a depth of 10 nm from the surface of the Nb₃N₅ film in the photoelectrode of Example 3. Furthermore, the AES spectrum from the surface of the Nb₃N₅ film in the photoelectrode of Example 3 confirmed that the film composition of the Nb₃N₅ film was almost equal to Nb/N=⅗ and thus Nb₃N₅ was produced. FIG. 12 shows the sheet resistance of an exposed portion (electrode extraction portion) of the GZO film in the photoelectrode of Example 3 (the result “after Nb₃N₅ deposition” in FIG. 12). There was little difference in the sheet resistance before and after the formation of the Nb₃N₅ film, which indicates that the GZO film was remained unchanged even after the formation of the Nb₃N₅ film.

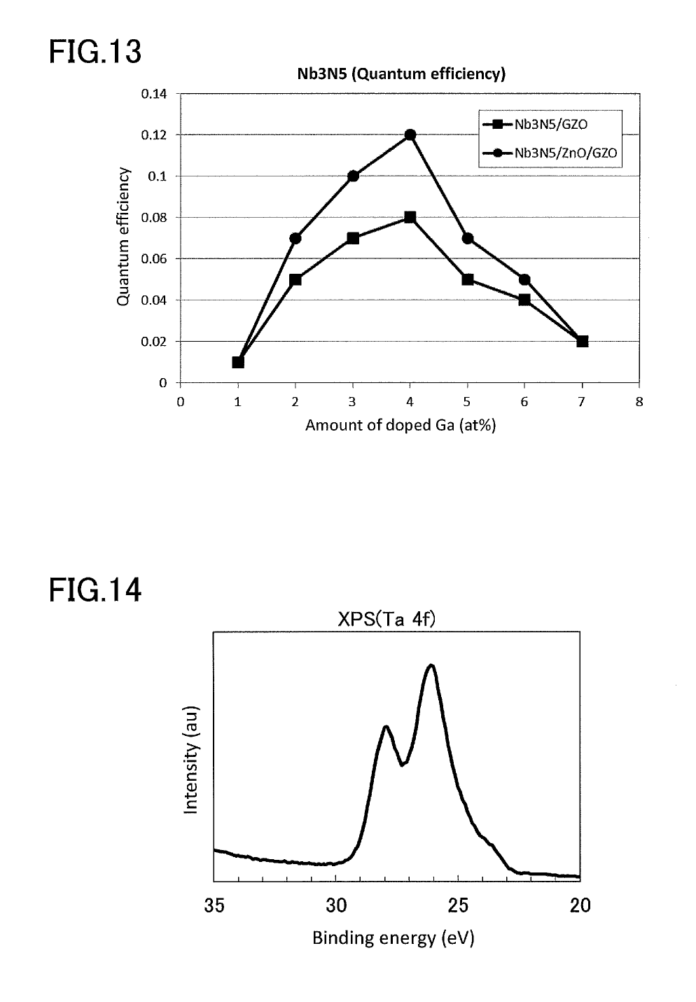

A photoelectrochemical cell was fabricated using the photoelectrode of Example 3 in the same manner as in Example 1. This photoelectrochemical cell was irradiated with sunlight from the photoelectrode side, and the quantum efficiency was measured based on a photocurrent generated therein. FIG. 13 shows the result (the result of “Nb₃N₅/GZO” in FIG. 13). This result confirmed that a photoelectrochemical cell using the photoelectrode of Example 3 could achieve high quantum efficiency, particularly a cell using the photoelectrode including a GZO film doped with 2 to 6% of Ga and having a low sheet resistance could achieve higher quantum efficiency, and more particularly a cell using the photoelectrode including an epitaxial GZO film doped with 2 to 4% of Ga could achieve even higher quantum efficiency

### Example 4

A photoelectrode of Example 4 was fabricated in the same manner as in Example 3, except that a ZnO film was provided between the GZO film and the Nb₃N₅ film of the photoelectrode of Example 3. First, in a sputtering apparatus, sputtering was performed using each of the prepared ZnO targets in an Ar gas flow atmosphere at a flow rate of 3.38×10⁻³ Pa·m³/s (20 sccm), onto a (20-inch square) sapphire substrate heated to 300° C. and having R-plane exposed on its surface, in the same manner as in Example 3. Thus, GZO films, respectively, in which 1%, 2%, 3%, 4%, 5%, 6%, 7%, and 8% of Zn were substituted by Ga, were formed. Next, sputtering was performed using a ZnO target in which Zn was not substituted by Ga, so that a ZnO semiconductor film with a thickness of 50 nm was provided on each of the GZO films. Next, a Nb₃N₅ film was formed on the ZnO semiconductor film in the same manner as in Example 3. Thus, the photoelectrode of Example 4 was obtained.

A photoelectrochemical cell was fabricated using the photoelectrode of Example 4 in the same manner as in Example 1. This photoelectrochemical cell was irradiated with sunlight from the photoelectrode side, and the quantum efficiency was measured based on a photocurrent generated therein. FIG. 13 shows the result (the result of “Nb₃N₅/ZnO/GZO” in FIG. 13). This result confirmed that a photoelectrochemical cell using the photoelectrode of Example 4 could achieve high quantum efficiency, particularly a cell using the photoelectrode including a GZO film doped with 2 to 6% of Ga and having a low sheet resistance could achieve higher quantum efficiency, and more particularly a cell using the photoelectrode including an epitaxial GZO film doped with 2 to 4% of Ga could achieve even higher quantum efficiency. Furthermore, it was also confirmed that, due to the charge separation effect of the ZnO film, the photoelectrode of Example 4 had higher quantum efficiency than the photoelectrode of Example 3 without a ZnO film provided therein.

### Example 5

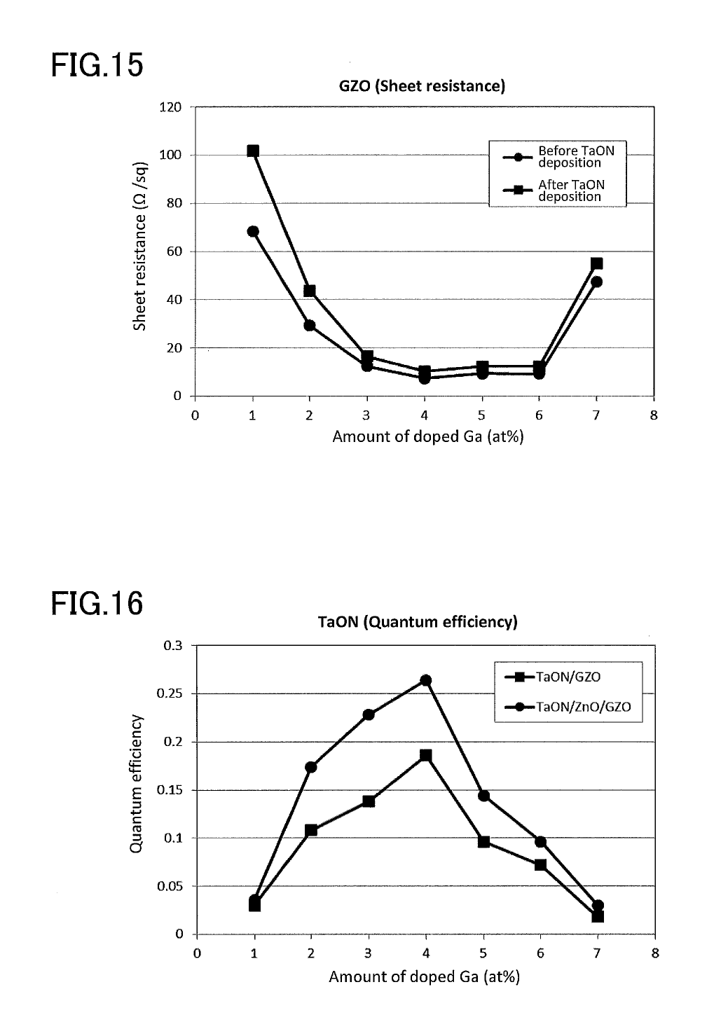

A photoelectrode was fabricated in the same manner as in Example 1, except that tertiary-butylimino tris-(ethylmethylamino)tantalum ((CH₃)₃CN=Ta(N(C₂H₅)CH₃)₃) was used instead of tertiary-butylimino tris-(ethylmethylamino)niobium ((CH₃)₃CN=Nb(N(C₂H₅)CH₃)₃) used in the MOCVD of Example 1. In other words, the photoelectrode of Example 5 was a photoelectrode having the same structure as the photoelectrode of Example 1 but including a TaON film instead of a NbON film. FIG. 14 shows the XPS spectrum at a depth of 10 nm from the surface of the TaON film in the photoelectrode of Example 5. Furthermore, the AES spectrum from the surface of the TaON film in the photoelectrode of Example 5 confirmed that the film composition of the TaON film was almost equal to Ta/O/N=1/1/1 and thus TaON was produced. FIG. 15 shows the sheet resistance of an exposed portion (electrode extraction portion) of the GZO film in the photoelectrode of Example 5 (the result “after TaON deposition” in FIG. 15). There was little difference in the sheet resistance before and after the formation of the TaON film, which indicates that the GZO film was remained unchanged even after the formation of the TaON film.

A photoelectrochemical cell was fabricated using the photoelectrode of Example 5 in the same manner as in Example 1. This photoelectrochemical cell was irradiated with sunlight from the photoelectrode side, and the quantum efficiency was measured based on a photocurrent generated therein. FIG. 16 shows the result (the result of “TaON/GZO” in FIG. 16). This result confirmed that a photoelectrochemical cell using the photoelectrode of Example 5 could achieve high quantum efficiency, particularly a cell using the photoelectrode including a GZO film doped with 2 to 6% of Ga and having a low sheet resistance could achieve higher quantum efficiency, and more particularly a cell using the photoelectrode including an epitaxial GZO film doped with 2 to 4% of Ga could achieve even higher quantum efficiency

It was also confirmed that an additional ZnO film provided between the GZO film and the TaON film in the photoelectrode of Example 5 produced the same effect of the additional ZnO films in Examples 2 and 4.

### Example 6

A Ta₃N₅ film was formed instead of a TaON film by performing MOCVD in the same manner as in Example 5, except that only ammonia (1.69×10⁻³ Pa·m³/s (10 sccm) was injected onto a substrate instead of injecting a gas mixture containing ammonia (1.69×10⁻³ Pa·m³/s (10 sccm) and water vapor (1.69×10⁻⁵ Pa·m³/s (0.1 sccm)). Thus, the photoelectrode of Example 6 including a sapphire substrate, a GZO film provided on the sapphire substrate, and a Ta₃N₅ film provided on the GZO film was obtained.

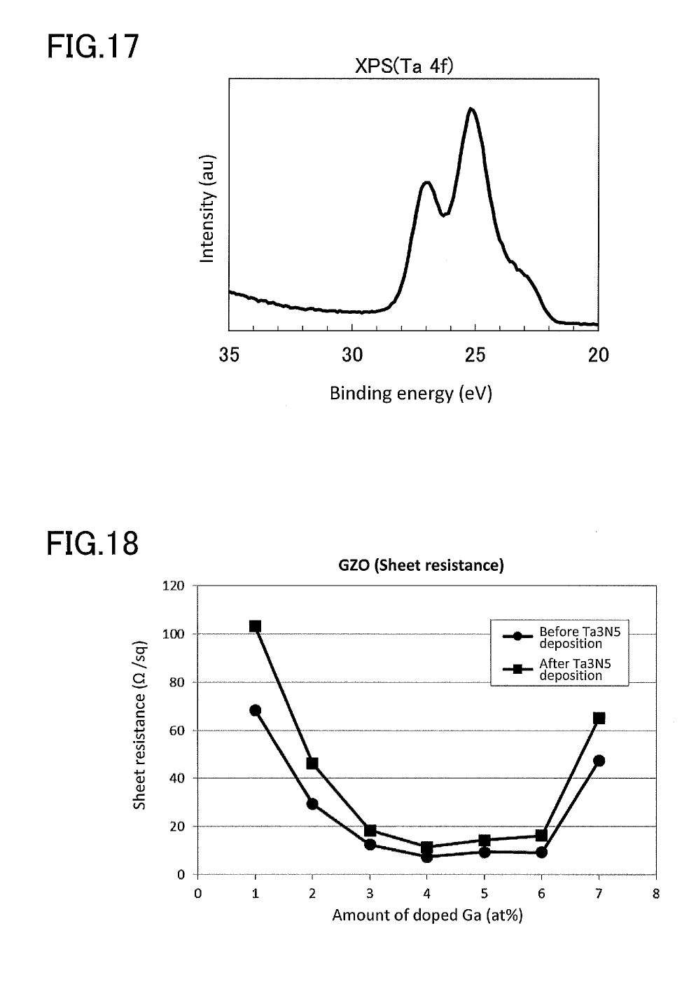

FIG. 17 shows the XPS spectrum at a depth of 10 nm from the surface of the Ta₃N₅ film in the photoelectrode of Example 6. Furthermore, the AES spectrum from the surface of the Ta₃N₅ film in the photoelectrode of Example 6 confirmed that the film composition of the Ta₃N₅ film was almost equal to Ta/N=⅗ and thus Ta₃N₅ was produced. FIG. 18 shows the sheet resistance of an exposed portion (electrode extraction portion) of the GZO film in the photoelectrode of Example 3 (the result “after Ta₃N₅ deposition” in FIG. 18). There was little difference in the sheet resistance before and after the formation of the Ta₃N₅ film, which indicates that the GZO film was remained unchanged even after the formation of the Ta₃N₅ film.

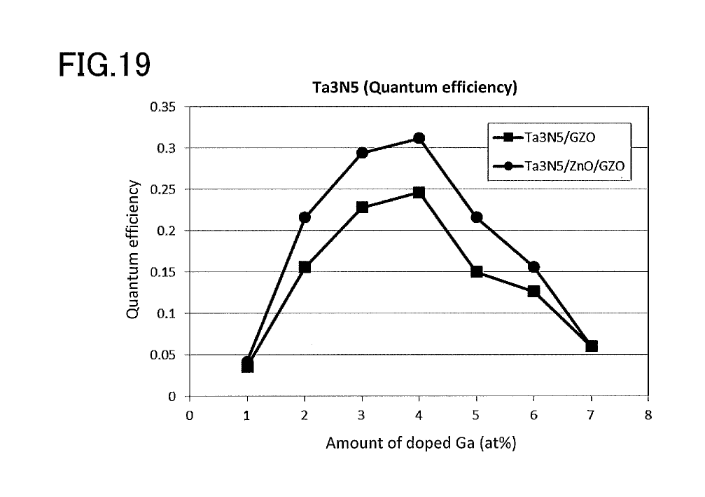

A photoelectrochemical cell was fabricated using the photoelectrode of Example 6 in the same manner as in Example 1. This photoelectrochemical cell was irradiated with sunlight from the photoelectrode side, and the quantum efficiency was measured based on a photocurrent generated therein. FIG. 19 shows the result (the result of “Ta₃N₅/GZO” in FIG. 19). This result confirmed that a photoelectrochemical cell using the photoelectrode of Example 6 could achieve high quantum efficiency, particularly a cell using the photoelectrode including a GZO film doped with 2 to 6% of Ga and having a low sheet resistance could achieve higher quantum efficiency, and more particularly a cell using the photoelectrode including an epitaxial GZO film doped with 2 to 4% of Ga could achieve even higher quantum efficiency

It was also confirmed that an additional ZnO film provided between the GZO film and the Ta₃N₅ film in the photoelectrode of Example 6 produced the same effect of the additional ZnO films in Examples 2 and 4.

### INDUSTRIAL APPLICABILITY

According to the photoelectrode of the present disclosure, it is possible to form a semiconductor film composed of a metal nitride or a metal oxynitride using high-temperature ammonia and to improve the orientation of such a semiconductor film composed of a metal nitride or a metal oxynitride. Therefore, it is possible to further improve the properties (quantum efficiency) of the optical semiconductor capable of splitting water to produce hydrogen and oxygen under irradiation with light, and as a result, to obtain more hydrogen and oxygen. In addition, the use of Ta₃N₅ or Nb₃N₅ as a metal nitride or NbON or TaON as a metal oxynitride makes it possible to utilize visible light. Thus, it can be said that the present disclosure has high industrial applicability.

1. A photoelectrode comprising:
a substrate;
a ZnO conductive film which is provided on the substrate and in which Zn is partially substituted by Ga; and
a semiconductor film which is provided on an opposite side of the substrate with respect to the ZnO conductive film and which is composed of a nitride or an oxynitride of at least one metal element selected from metal elements of group 5A.
wherein a ratio of a number of Ga atoms to a total number of Zn atoms and Ga atoms in the ZnO conductive film is 2 at % or more and 6 at % or less in atomic percent.

2. (canceled)

3. The photoelectrode according to claim 1, wherein the ratio of the total number of Ga atoms to the total number of Zn atoms and Ga atoms in the ZnO conductive film is 2 at % or more and 4 at % or less in atomic percent.

4. The photoelectrode according to claim 1, wherein the ZnO conductive film is an epitaxial film.

5. The photoelectrode according to claim 1, further comprising a ZnO semiconductor film disposed between the ZnO conductive film and the semiconductor film.

6. The photoelectrode according to claim 5, wherein the ZnO semiconductor film is an epitaxial film.

7. The photoelectrode according to claim 1, wherein a portion of the ZnO conductive film is exposed without being covered with the semiconductor film.

8. The photoelectrode according to claim 1, wherein the semiconductor film is a semiconductor film composed of at least one selected from a Nb nitride, a Ta nitride, a Nb oxynitride, and a Ta oxynitride.

9. The photoelectrode according to claim 8, wherein the semiconductor film is a semiconductor film composed of at least one nitride selected from Nb₃N₅ and Ta₃N₅.

10. The photoelectrode according to claim 8, wherein the semiconductor film is a semiconductor film composed of at least one oxynitride selected from NbON and TaON.

11. A photoelectrochemical cell comprising:
the photoelectrode according to claim 1;
a counter electrode electrically connected to the ZnO conductive film of the photoelectrode; and
a container containing the photoelectrode and the counter electrode.

12. The photoelectrochemical cell according to claim 11, further comprising a water-containing electrolyte solution in contact with a surface of the photoelectrode and a surface of the counter electrode in the container.

13. A method for producing a photoelectrode, comprising:
forming, on a substrate, a ZnO conductive film in which Zn is partially substituted by Ga; and
forming, on an opposite side of the substrate with respect to the ZnO conductive film, a semiconductor film composed of a nitride or an oxynitride of at least one metal element selected from metal elements of group 5A, using ammonia.
